(19) United States
(12) Patent Application Publication
(10) Pub. No.: US 2026/0371707 A1
(43) Pub. Date: Nov. 19, 2026

(54) INTEGRATED CIRCUIT DEVICE

(71) Applicant: Samsung Electronics Co., Ltd., Suwon-si (KR)

(72) Inventors: Soobin Han, Suwon-si (KR); Soomin Son, Suwon-si (KR); Soyeong Ahn, Suwon-si (KR); Suk Yang, Suwon-si (KR); Sangmoon Lee, Suwon-si (KR)

(73) Assignee: Samsung Electronics Co., Ltd., Suwon-si (KR)

(21) Appl. No.: 19/427,048

(22) Filed: Dec. 19, 2025

(30) Foreign Application Priority Data
May 14, 2025 (KR) 10-2025-0062826

(51) Int. Cl. H10D 84/83; H10D 30/00; H10D 30/01; H10D 30/43; H10D 62/10; H10D 62/13; H10D 64/23; H10D 84/01; H10W 20/41

(52) U.S. Cl. CPC H10D 84/8312; H10D 30/43; H10D 30/502; H10D 62/121; H10D 62/151; H10D 64/256; H10D 84/832; H10W 20/435; H10D 30/014; H10D 30/0191; H10D 84/0149

(57) ABSTRACT

Provided is an integrated circuit device including a plurality of gate lines spaced apart in a first substantially horizontal direction and extending in a second substantially horizontal direction, a plurality of lower source/drain regions of a first conductivity type arranged between the plurality of gate lines adjacent to one another at a first vertical level, a plurality of upper source/drain regions of a second conductivity type arranged between the plurality of gate lines adjacent to one another at a second vertical level and overlapping the lower source/drain regions in a substantially vertical direction, a nanosheet stack connected to the plurality of lower source/drain regions or the plurality of upper source/drain regions, a plurality of buffer layers arranged under the plurality of lower source/drain regions, respectively, and a plurality of backside contacts penetrating the plurality of buffer layers and respectively connected to the plurality of lower source/drain regions.

### CROSS-REFERENCE TO RELATED APPLICATIONS

This present application claims priority to and the benefit under 35 U.S.C. § 119(a)-(d) of Korean Patent Application No. 10-2025-0062826, filed on May 14, 2025, in the Korean Intellectual Property Office, the entire disclosure of which is incorporated herein by reference.

### FIELD

The disclosed concepts relate to an integrated circuit device, and more particularly, to an integrated circuit device including vertically stacked field effect transistors.

### BACKGROUND

As the down-scaling of integrated circuit devices progresses rapidly, there is a limit to increasing the number of transistors per unit area in a two-dimensional circuit with horizontally arranged NMOS and PMOS field effect transistors in a gate-all-around (GAA) structure. Accordingly, a new technology is needed to further improve the degree of integration by increasing the number of transistors per unit area while improving the electrical performance of each of the NMOS field effect transistors and PMOS field effect transistors.

### SUMMARY

The disclosed concepts provide an integrated circuit device with stable performance and improved reliability in a nanosheet field effect transistor.

According to aspects of the disclosed concepts, there is provided an integrated circuit device including a plurality of gate lines spaced apart in a first substantially horizontal direction and extending in a second substantially horizontal direction crossing the first substantially horizontal direction, a plurality of lower source/drain regions of a first conductivity type arranged between the plurality of gate lines adjacent to one another at a first vertical level, a plurality of upper source/drain regions of a second conductivity type arranged between the plurality of gate lines adjacent to one another at a second vertical level higher than the first vertical level and overlapping the lower source/drain regions in a substantially vertical direction, a nanosheet stack including at least one nanosheet connected to the plurality of lower source/drain regions or the plurality of upper source/drain regions, a plurality of buffer layers arranged under the plurality of lower source/drain regions, respectively, and a plurality of backside contacts penetrating the plurality of buffer layers and respectively connected to the plurality of lower source/drain regions.

According to aspects of the disclosed concepts, there is provided an integrated circuit device including a plurality of gate lines spaced apart in a first substantially horizontal direction and extending in a second substantially horizontal direction crossing the first substantially horizontal direction, a plurality of source/drain regions arranged between adjacent ones of the plurality of gate lines, a nanosheet stack including one or more nanosheets connected to the plurality of source/drain regions, a plurality of buffer layers arranged under the plurality of source/drain regions, respectively, and a plurality of backside contacts penetrating the plurality of buffer layers and respectively connected to the plurality of source/drain regions.

According to aspects of the disclosed concepts, there is provided an integrated circuit device including a plurality of lower source/drain regions, a plurality of upper source/drain regions spaced apart in a substantially vertical direction from the plurality of lower source/drain regions, a lower nanosheet stack connected to the plurality of lower source/drain regions and including a plurality of lower nanosheets spaced apart from one another in the substantially vertical direction, an upper nanosheet stack connected to the plurality of upper source/drain regions and including a plurality of upper nanosheets spaced apart from one another in the substantially vertical direction, a plurality of gate lines spaced apart from one another in a first substantially horizontal direction and extending in a second substantially horizontal direction crossing the first substantially horizontal direction, and surrounding the plurality of lower nanosheets and the plurality of upper nanosheets, a plurality of upper contacts connected to the plurality of upper source/drain regions, a plurality of buffer layers including silicon germanium and arranged under the plurality of lower source/drain regions, and a plurality of backside contacts respectively penetrating the plurality of buffer layers and connected to the plurality of lower source/drain regions.

According to aspects of the disclosed concepts, there is provided a method of manufacturing an integrated circuit device, the method including forming a plurality of recesses in a substrate and forming a plurality of placeholders respectively filling the plurality of recesses, forming a buffer layer covering the substrate and the placeholders, forming a plurality of nanosheet stacks on the buffer layer, forming a plurality of source/drain regions arranged between the plurality of nanosheet stacks and overlapping the plurality of placeholders in a substantially vertical direction, forming a plurality of gate lines spaced apart from one another in a first substantially horizontal direction and extending in a second substantially horizontal direction crossing the first substantially horizontal direction and surrounding the plurality of nanosheet stacks, removing a bottom surface of the substrate to expose a bottom surface of the plurality of placeholders, removing the exposed plurality of placeholders, and forming a plurality of backside contacts penetrating the buffer layer and connected to the plurality of source/drain regions, respectively, wherein the forming of the buffer layer includes forming a lower buffer layer covering a top surface of the plurality of placeholders and a top surface of the substrate and including silicon germanium, and forming an upper buffer layer covering the lower buffer layer and including silicon.

In some embodiments, the plurality of placeholders include a first placeholder and a second placeholder spaced apart from the first placeholder in a substantially horizontal direction, and a vertical level of the top surface of the first placeholder may be lower than a vertical level of the top surface of the second placeholder.

In some embodiments, the forming of the lower buffer layer is formed such that a thickness of the lower buffer layer overlapping the first placeholder in a substantially vertical direction is greater than a thickness of the lower buffer layer overlapping the second placeholder in the substantially vertical direction.

In some embodiments, the forming of the lower buffer layer includes epitaxially growing the lower buffer layer so that a top surface of the lower buffer layer is coplanar.

In some embodiments, the forming of the plurality of source/drain regions includes forming the plurality of lower source/drain regions penetrating a part of the buffer layer, forming a plurality of insulating patterns covering the plurality of lower source/drain regions, and forming a plurality of upper source/drain regions spaced apart from the plurality of lower source/drain regions in the substantially vertical direction with the plurality of insulating patterns therebetween.

In some embodiments, the forming of the plurality of backside contacts is formed such that a width of the plurality of backside contacts in the first substantially horizontal direction is greater than a maximum width of the plurality of source/drain regions.

In some embodiments, the method may further include forming a plurality of backside gate contacts spaced apart from the plurality of backside contacts in the first substantially horizontal direction and respectively connected to the plurality of gate lines.

In some embodiments, a vertical level of a bottom surface of the plurality of backside contacts and a vertical level of a bottom surface of the plurality of backside gate contacts are different from one another.

In some embodiments, the forming of the plurality of backside gate contacts is performed prior to the forming of the plurality of backside contacts.

In some embodiments, the forming of the plurality of backside gate contacts includes removing a part of the buffer layer so that the plurality of gate lines are exposed, forming a gap-fill insulating layer covering a sidewall of the buffer layer, and forming a plurality of backside gate contacts covering a sidewall of the gap-fill insulating layer and connected to the plurality of gate lines, respectively.

### BRIEF DESCRIPTION OF THE DRAWINGS

Embodiments will be more clearly understood from the following detailed description taken in conjunction with the accompanying drawings in which:

FIG. 1 is a plan layout diagram for explaining an integrated circuit device according to embodiments;

FIG. 2 is a cross-sectional view taken along a line X1-X1′ of FIG. 1;

FIG. 3 is an enlarged cross-sectional view of a region EX1 of FIG. 2A;

FIG. 4 is a cross-sectional view for explaining an integrated circuit device according to embodiments;

FIG. 5 is an enlarged cross-sectional view of a region EX2 of FIG. 4;

FIG. 6 is a cross-sectional view for explaining an integrated circuit device according to embodiments;

FIGS. 7 to 25 are cross-sectional views of a part corresponding to a cross section taken along a line X1-X1′ of FIG. 1 and illustrate, according to a process sequence, a method of manufacturing an integrated circuit device according to embodiments; and

FIGS. 26 to 28 are cross-sectional views of a part corresponding to a cross section taken along a line X1-X1′ of FIG. 1 and illustrate, according to a process sequence, a method of manufacturing an integrated circuit device according to embodiments.

### DETAILED DESCRIPTION

Hereinafter, embodiments of the inventive concept will be described in detail with reference to the accompanying drawings.

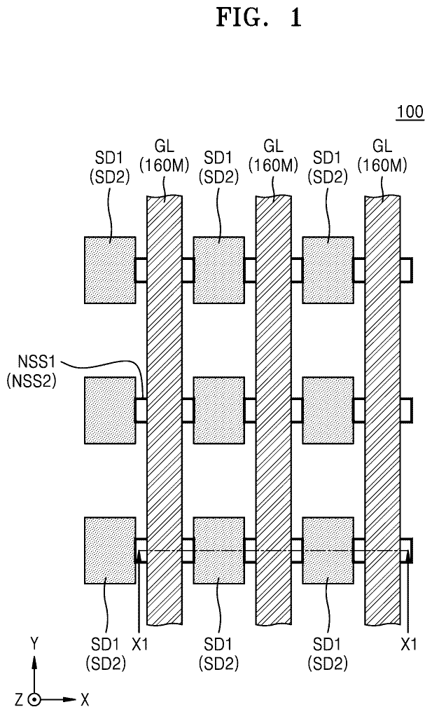

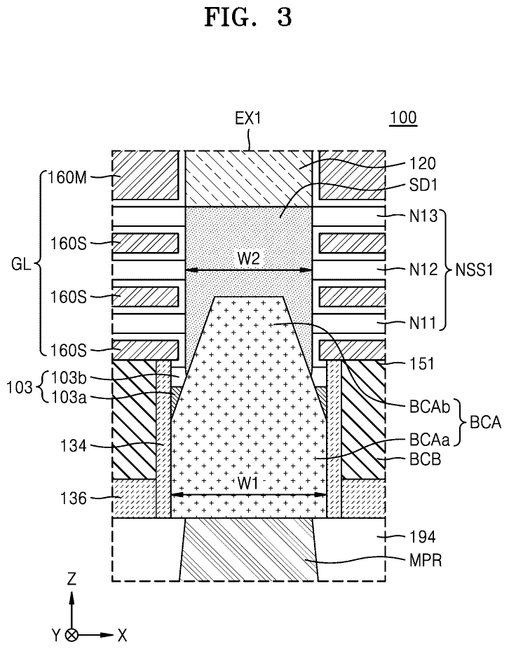

FIGS. 1 to 3 illustrate an integrated circuit device 100 including a field effect transistor having a gate-all-around structure including an active region and a gate surrounding the active region, each having a shape of a nanowire or nanosheet and including a first transistor TR1 and a second transistor TR2 stacked in a vertical direction (Z direction).

The integrated circuit device 100 may include a backside structure BSS and a frontside structure (FSS) on the backside structure BSS. According to embodiments, the backside structure BSS may include a plurality of backside contacts BCA, a plurality of backside gate contacts BCB, a plurality of second gap-fill insulating layers 134, a plurality of third gap-fill insulating layers 136, a plurality of lower insulating layers 194, and a metal power rail MPR. According to embodiments, the frontside structure FSS may include a buffer layer 103, a plurality of nanosheet stacks NSS1 and NSS2, a plurality of gate lines GL, a plurality of lower source/drain regions SD1, a plurality of upper source/drain regions SD2, a plurality of upper contacts CA, an upper insulation structure 180, a via contact VA, an upper insulation layer 186, and a wiring line M1.

The integrated circuit device 100 may include the first transistor TR1 arranged at a first vertical level and the second transistor TR2 arranged at a second vertical level higher than the first vertical level. The first transistor TR1 and the second transistor TR2 may be arranged to overlap one another in the vertical direction (Z direction).

The plurality of gate lines GL may be arranged on the buffer layer 103. The plurality of gate lines GL may be spaced apart from one another in the first horizontal direction (X direction) and may extend long in the second horizontal direction (Y direction) crossing the first horizontal direction (X direction).

The plurality of nanosheet stacks NSS1 and NSS2 may be arranged at positions overlapping the plurality of gate lines GL in the vertical direction (Z direction). The plurality of gate lines GL may surround the plurality of nanosheets included in the plurality of nanosheet stacks NSS1 and NSS2, respectively. In the present specification, the term “nanosheet” may refer to a conductive structure having a cross-section substantially perpendicular to a direction in which a current flows. It should be understood that the nanosheet includes nanowires.

In embodiments, the plurality of nanosheet stacks NSS1 and NSS2 may include a plurality of lower nanosheet stacks NSS1 included in the first transistor TR1 and a plurality of upper nanosheet stacks NSS2 included in the second transistor TR2.

The plurality of lower nanosheet stacks NSS1 may include a first lower nanosheet N11, a second lower nanosheet N12, and a third lower nanosheet N13 overlapping one another in the vertical direction (Z direction). The first lower nanosheet N11, the second lower nanosheet N12, and the third lower nanosheet N13 may have different vertical distances (Z-direction distances) from the buffer layer 103.

The plurality of upper nanosheet stacks NSS2 may include a first upper nanosheet N21, a second upper nanosheet N22, and a third upper nanosheet N23 overlapping one another in the vertical direction (Z direction) on the plurality of lower nanosheet stacks NSS1. The first upper nanosheet N21, the second upper nanosheet N22, and the third upper nanosheet N23 may have different vertical distances (Z-direction distances) from the buffer layer 103.

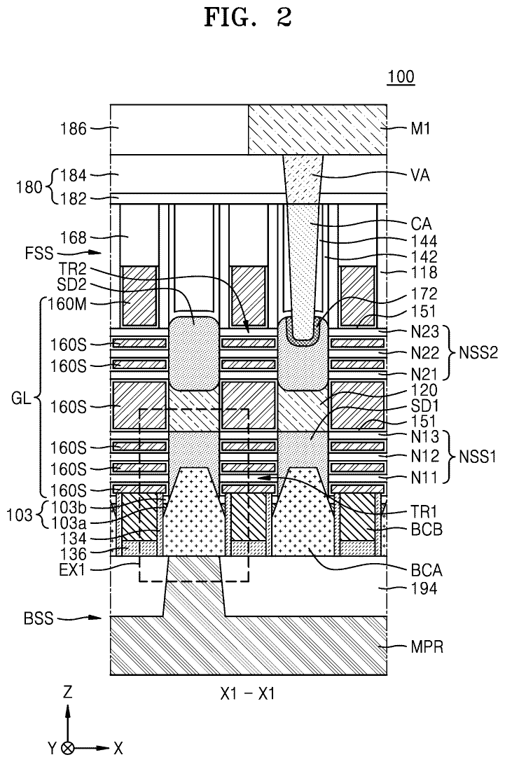

Although FIG. 2 illustrates a case in which the planar shapes of the nanosheet stacks NSS1 and NSS2 are approximately rectangular, the embodiments are not limited thereto. The nanosheet stacks NSS1 and NSS2 may have various planar shapes according to a planar shape of each of the gate lines GL.

Each of a plurality of nanosheets included in the nanosheet stacks NSS1 and NSS2 may function as a channel region. For example, the first lower nanosheet N11, the second lower nanosheet N12, and the third lower nanosheet N13 included in the lower nanosheet stack NSS1 may function as channel regions, respectively. Likewise, each of the first upper nanosheet N21, each of the second upper nanosheet N22, and the third upper nanosheet N23 included in the upper nanosheet stack NSS2 may function as a channel region.

In embodiments, the plurality of nanosheets may have substantially the same thickness in the vertical direction (Z direction). In embodiments, at least some of the plurality of nanosheets may have different thicknesses in the vertical direction (Z direction). In embodiments, each of the plurality of nanosheets included in the nanosheet stacks NSS1 and NSS2 may include a Si layer, a SiGe layer, or a combination thereof.

As illustrated in FIG. 2, the plurality of nanosheets included in one nanosheet stack NSS1 or NSS2 may have the same or similar size in the first horizontal direction (X direction). In embodiments, unlike the illustration in FIG. 2, at least some of the plurality of nanosheets included in one nanosheet stack NSS1 or NSS2 may have different sizes in the first horizontal direction (X direction).

In this embodiment, a case where each of the plurality of nanosheet stacks NSS1 and NSS2 includes three nanosheets has been illustrated, but embodiments are not limited to those illustrated. For example, each of the nanosheet stacks NSS1 and NSS2 may include at least one nanosheet, and the number of nanosheets constituting the nanosheet stacks NSS1 and NSS2 is not particularly limited.

The first transistor TR1 may include a lower nanosheet stack NSS1 and a pair of lower source/drain regions SD1 respectively arranged on both sides of the lower nanosheet stack NSS1 and in contact with each of the first lower nanosheet N11, the second lower nanosheet N12, and the third lower nanosheet N13.

The second transistor TR2 may include an upper nanosheet stack NSS2 and a pair of upper source/drain regions SD2 respectively arranged on both sides of the upper nanosheet stack NSS2 and in contact with each of the first upper nanosheet N21, the second upper nanosheet N22, and the third upper nanosheet N23.

Each of the plurality of upper source/drain regions SD2 may overlap each of the plurality of lower source/drain regions SD1 in the vertical direction (Z direction). The plurality of upper source/drain regions SD2 may be spaced apart from the backside structure BSS in the vertical direction (Z direction) with the plurality of lower source/drain regions SD1 therebetween.

Each of the lower source/drain regions SD1 and the upper source/drain regions SD2 may include an epitaxially grown semiconductor layer. In embodiments, the lower source/drain regions SD1 and the upper source/drain regions SD2 may include a group IV element semiconductor, a group IV-IV compound semiconductor, or a combination thereof.

In embodiments, the first transistor TR1 may be a PMOS field effect transistor. The lower source/drain regions SD1 included in the first transistor TR1 may include a semiconductor layer doped with a p-type dopant. For example, the lower source/drain regions SD1 may include a Si layer doped with a p-type dopant or a SiC layer doped with a p-type dopant. The p-type dopants may be selected from boron (B) and gallium (G).

In embodiments, the second transistor TR2 may be an NMOS field effect transistor. The upper source/drain regions SD2 included in the second transistor TR2 may include a semiconductor layer doped with an n-type dopant. For example, the upper source/drain regions SD2 may include a SiGe layer doped with an n-type dopant. The n-type dopants may be selected from phosphorus (P), arsenic (As), and antimony (Sb). However, embodiments are not limited thereto, and the first transistor TR1 may be an NMOS field effect transistor, and the second transistor TR2 may be a PMOS field effect transistor.

A plurality of insulating patterns 120 may be arranged between the plurality of lower source/drain regions SD1 and the plurality of upper source/drain regions SD2, respectively. The plurality of lower source/drain regions SD1 and the plurality of upper source/drain regions SD2 may be spaced apart from one another in the vertical direction (Z direction) with the plurality of insulating patterns 120 therebetween. The insulating pattern 120 may include silicon nitride (SiN), silicon oxide (SiO), SiCN, SiBN, SiON, SiOCN, SiBCN, SiOC, or a combination thereof. The terms “SiN”, “SiO”, “SiCN”, “SiBN”, “SiON”, “SiOCN”, “SiBCN”, and “SiOC” used herein, refer to materials including elements included in each of the terms, and are not chemical formulae representing a stoichiometric relationship. In embodiments, the insulating patterns 120 may have a double layer structure including different materials.

A pair of upper source/drain regions SD2 constituting the second transistor TR2 may fill recesses formed on the insulating patterns 120, respectively. The lowest surface level of the recess may be lower than the lowest surface level of the upper nanosheet stack NSS2.

The first transistor TR1 and the second transistor TR2, which overlap one another in the vertical direction (Z direction), may share one gate line GL. That is, the gate line GL constituting the one selected first transistor TR1 and the gate line GL constituting the second transistor TR2 overlapping the one selected first transistor TR1 in the vertical direction (Z direction) may have an integrally connected structure.

Each of the plurality of gate lines GL may include a main gate part 160M and a plurality of sub-gate parts 160S, which are integrally connected to one another. The main gate part 160M may extend lengthwise in the second horizontal direction (Y direction) while covering the top surface of the second nanosheet stack NSS2.

At least one sub-gate portion 160S may cover at least one lower nanosheet N11, N12, and N13, and may face the lower source/drain region SD1 in the first horizontal direction (X direction). At least one sub-gate portion 160S may have a surface facing the lower nanosheets N11, N12, and N13, and a surface facing the lower source/drain region SD1. At least one sub-gate portion 160S may cover at least one upper nanosheet N21, N22, and N23, and may face the upper source/drain region SD2 in the first horizontal direction (X direction). At least one sub-gate portion 160S may have a surface facing the upper nanosheets N21, N22, and N23 and a surface facing the upper source/drain region SD2.

A maximum width of the sub-gate portion 160S in the first horizontal direction (X direction) may be greater than a maximum width of the main gate portion 160M. In the vertical direction (Z direction), the thickness of each of the sub-gate parts 160S may be less than the thickness of the main gate portion 160M.

The gate lines GL may include metal, metal nitride, metal carbide, or a combination thereof. The metal may be selected from Ti, W, Ru, Nb, Mo, Hf, Ni, Co, Pt, Yb, Tb, Dy, Er, and Pd. The metal nitride may be selected from TiN and TaN. The metal carbide may be TiAlC. However, the material constituting the gate lines GL is not limited to the above examples.

A gate dielectric layer 151 may be arranged between the gate line GL and each of the plurality of lower nanosheets N11, N12, and N13 and the plurality of upper nanosheets N21, N22, and N23. According to embodiments, the gate dielectric layer 151 may have a stacked structure of an interface layer and a high dielectric layer. The interface layer may include a low dielectric material layer having a dielectric constant of about 9 or less, for example, a silicon oxide layer, a silicon oxynitride layer, or a combination thereof. According to embodiments, the interface layer may be omitted. The high dielectric layer may be made of a material having a higher dielectric constant than that of a silicon oxide layer. For example, the high dielectric layer may have a dielectric constant of about 10 to about 25. The high dielectric layer may be made of hafnium oxide, but is not limited thereto.

In embodiments, the plurality of lower nanosheets N11, N12, and N13 and the plurality of upper nanosheets N21, N22, and N23 may include semiconductor layers including the same element. In an example, each of the plurality of lower nanosheets N11, N12, and N13 and the plurality of upper nanosheets N21, N22, and N23 may include a Si layer. In embodiments, the plurality of lower nanosheets N11, N12, and N13 and the plurality of upper nanosheets N21, N22, and N23 may include an undoped Si layer. In embodiments, the plurality of lower nanosheets N11, N12, and N13 may include a Si layer doped with a dopant of the same conductivity type as that of the lower source/drain region SD1, and the plurality of upper nanosheets N21, N22, and N23 may include a Si layer doped with a dopant of the same conductivity type as that of the upper source/drain region SD2. In embodiments, the plurality of lower nanosheets N11, N12, and N13 may include a Si layer doped with a dopant of the opposite conductivity type as that of the lower source/drain region SD1, and the plurality of upper nanosheets N21, N22, and N23 may include a Si layer doped with a dopant of the opposite conductivity type as that of the upper source/drain region SD2.

Both sidewalls of the gate line GL may be covered with an insulating spacer 118 on the second nanosheet stack NSS2. The gate dielectric layer 151 may include a portion arranged between the gate line GL and the insulating spacer 118. The insulating spacer 118 may be spaced apart from the gate line GL with the gate dielectric layer 151 therebetween. The insulating spacer 118 may include silicon nitride, SiCN, SiBN, SiON, SiOCN, SiBCN, SiOC, or a combination thereof. For example, the insulating spacer 118 may include a double layer of an inner silicon nitride layer in contact with the gate dielectric layer 151 and a SiOCN layer spaced apart from the gate dielectric layer 151 with the inner silicon nitride layer therebetween, but is not limited thereto.

A top surface of the gate line GL may be covered with a capping insulating pattern 168. The capping insulating pattern 168 may include a silicon nitride layer. The capping insulating pattern 168 may cover a top surface of each of the gate line GL and the gate dielectric layer 151.

The insulating spacer 118 and the upper source/drain region SD2 may be covered with an insulating liner 142. The insulating liner 142 may include silicon nitride (SiN), silicon oxide (SiO), SiCN, SiBN, SiON, SiOCN, SiBCN, SiOC, or a combination thereof. In embodiments, the insulating liner 142 may be omitted. An inter-gate insulating layer 144 may be arranged on the insulating liner 142. The inter-gate insulating layer 144 may include a silicon nitride, a silicon oxide, SiON, SiOCN, or a combination thereof. When the insulating liner 142 is omitted, the inter-gate insulating layer 144 may be in contact with the plurality of lower source/drain regions SD.

The top surface of each of the upper contacts CA, the capping insulating patterns 168, and the inter-gate insulating layer 144 may be covered with an upper insulating structure 180. The upper insulating structure 180 may include an etching stop layer 182 and an interlayer insulating layer 184 sequentially stacked on each of the upper contacts CA, the plurality of capping insulating patterns 168, and the inter-gate insulating layer 144. The etching stop layer 182 may include a silicon carbide (SiC), a silicon nitride (SiN), a nitrogen-doped silicon carbide (SiC:N), SiOC, AlN, AION, AIO, AIOC, or a combination thereof. The interlayer insulating layer 184 may include an oxide layer, a nitride layer, an ultra-low-k (ULK) layer having an ultra-low dielectric constant K of about 2.2 to about 2.4, or a combination thereof. For example, the interlayer insulating layer 184 may include a tetraethylorthosilicate (TEOS) layer, a high-density plasma (HDP) oxide layer, a boro-phospho-silicate glass (BPSG) layer, a flowable chemical vapor deposition (FCVD) oxide layer, a SiON layer, a SiN layer, a SiOC layer, a SiCOH layer, or a combination thereof, but is not limited thereto.

A via contact VA may be arranged on the upper contact CA. The via contact VA may penetrate the upper insulating structure 180 and be in contact with the upper contact CA. Each of the upper source/drain regions SD2 may be configured to be electrically connected to the via contact VA through the metal silicide layer 172 and the upper contact CA. The bottom surface of the via contact VA may be in contact with the top surface of the upper contact CA. The via contact VA may include tungsten (W), molybdenum (Mo), and/or ruthenium (Ru), but is not limited thereto.

A wiring line M1 may be arranged to penetrate an upper insulating layer 186. The wiring line M1 may be connected to the via contact VA at the bottom of the wiring line M1. In some embodiments, the wiring line M1 may extend in the first horizontal direction (X direction). The wiring line M1 may include molybdenum (Mo), copper (Cu), tungsten (W), cobalt (Co), ruthenium (Ru), manganese (Mn), titanium (Ti), tantalum (Ta), aluminum (Al), a combination thereof, or an alloy thereof, but is not limited thereto.

The plurality of buffer layers 103 may be arranged under the plurality of lower source/drain regions SD1, respectively. Each of the plurality of buffer layers 103 may include a lower buffer layer 103a and an upper buffer layer 103b. The upper buffer layer 103b may be arranged below the lower source/drain region SD1, and the lower buffer layer 103a may be arranged below the upper buffer layer 103b. The lower buffer layer 103a and the upper buffer layer 103b may include different materials. For example, the upper buffer layer 103b may include silicon (Si), and the lower buffer layer 103a may include silicon germanium (SiGe). In this case, the germanium concentration of the lower buffer layer 103 a may be less than 5.5 %, but embodiments are not limited thereto. In another embodiment, the upper buffer layer 103b may be omitted, and the buffer layer 103 may include a silicon germanium single layer.

A plurality of backside contacts BCA may pass through the plurality of buffer layers 103, respectively and extend in a vertical direction (Z direction). The plurality of backside contacts BCA may be connected to the plurality of lower source/drain regions SD1, respectively. In some embodiments, each of the plurality of backside contacts BCA may include a metal, a conductive metal nitride, or a combination thereof. For example, each of the plurality of backside contacts BCA may include W, Cu, Al, Ti, Ta, TiN, TaN, alloys thereof, or a combination thereof, but is not limited thereto. A metal silicide layer may be arranged between the plurality of backside contacts BCA and the plurality of lower source/drain regions SD1.

The plurality of backside contacts BCA may be arranged to overlap the plurality of lower source/drain regions SD1 in the vertical direction (Z-direction), respectively. For example, the horizontal central axis of the plurality of backside contacts BCA may be arranged to coincide with the horizontal central axis of the plurality of lower source/drain regions SD1, but embodiments are not limited thereto.

Each of the plurality of backside contacts BCA may include a horizontal part BCAa and a protruding portion BCAb. The horizontal part BCAa may be arranged under the buffer layer 103 and may have a constant width in the first horizontal direction (X direction). A width W1 of the horizontal part BCAa in the first horizontal direction (X direction) may be greater than a width W2 of the lower source/drain region SD1 in the first horizontal direction (X direction). The protrusion part BCAb may penetrate the buffer layer 103 to be in contact with the lower source/drain region SD1. The protrusion part BCAb may be integrally formed with the horizontal part BCAa, and may have a tapered shape in which a width in the first horizontal direction (X direction) decreases as a distance from a top surface of the horizontal part BCAa increases, but embodiments are not limited thereto.

The second gap-fill insulating layer 134 may cover sidewalls of the plurality of buffer layers 103 and sidewalls of the plurality of backside contacts BCA. A pair of second gap-fill insulating layers 134 may be spaced apart from one another in the first horizontal direction (X direction) with the buffer layer 103 and the back side contact BCA therebetween. The sidewall of the upper buffer layer 103b, the sidewall of the lower buffer layer 103a, and the sidewall of the horizontal part BCAa may be arranged in a line in the vertical direction (Z direction). The width in the first horizontal direction (X direction) between the sidewalls of the plurality of buffer layers 103 respectively being in contact with the second gap-fill insulating layers 134 may be the same as the width W1 of the horizontal part BCAa in the first horizontal direction (X direction). That is, the first horizontal width between the sidewalls of the plurality of buffer layers 103 respectively being in contact with the second gap-fill insulating layers 134 may be greater than the first horizontal width W2 of the lower source/drain region SD1.

In embodiments, the second gap-fill insulating layer 134 may include silicon nitride (SiN), silicon oxide (SiO), SiCN, SiBN, SiON, SiOCN, SiBCN, SiOC, or a combination thereof.

The plurality of backside gate contacts BCB may be spaced apart from the plurality of backside contacts BCA in the first horizontal direction (X direction) with the second gap-fill insulating layer 134 therebetween. The plurality of backside gate contacts BCB may be connected to the plurality of gate lines GL overlapping in the vertical direction (Z direction), respectively. The plurality of backside gate contacts BCB may include W, Cu, Al, Ti, Ta, TiN, TaN, an alloy thereof, or a combination thereof, but are not limited thereto.

A third gap-fill insulating layer 136 may cover bottom surfaces of the plurality of backside gate contacts BCB. A sidewall of the third gap-fill insulating layer 136 may be in contact with a portion of a sidewall of the second gap-fill insulating layer 134. In embodiments, the third gap-fill insulating layer 136 may include silicon nitride (SiN), silicon oxide (SiO), SiCN, SiBN, SiON, SiOCN, SiBCN, SiOC, or a combination thereof.

A vertical level of a bottom surface of the plurality of backside contacts BCA may be different from a vertical level of a bottom surface of the plurality of backside gate contacts BCB. A vertical level of a bottom surface of the plurality of backside contacts BCA may be lower than a vertical level of a bottom surface of the plurality of backside gate contacts BCB. In addition, a length of the plurality of backside contacts BCA in the vertical direction (Z direction) may be greater than a length of the plurality of backside gate contacts BCB in the vertical direction (Z direction).

The lower insulating layer 194 may cover the backside contact BCA, the second gap-fill insulating layer 134, and the third gap-fill insulating layer 136. The metal power rail MPR may penetrate the lower insulating layer 194 and may be connected to the lower source/drain region SD1.

The integrated circuit device 100 illustrated in FIGS. 1 to 3 may include the lower buffer layer 103a including silicon germanium and the upper buffer layer 103b including silicon. Through the epitaxial process, the surface roughness of the plurality of nanosheet stacks NSS1 and NSS2 may be improved by forming the plurality of nanosheet stacks NSS1 and NSS2 on the buffer layer 103. Accordingly, electron mobility is improved and channel resistance is reduced, thereby improving electrical characteristics of the integrated circuit device 100.

In addition, by making the width W1 of the backside contact BCA in the first horizontal direction (X direction) greater than the width W2 of the lower source/drain area SD1 in the first horizontal direction (X direction), the contact resistance may be reduced, thereby improving the electrical characteristics of the integrated circuit device 100.

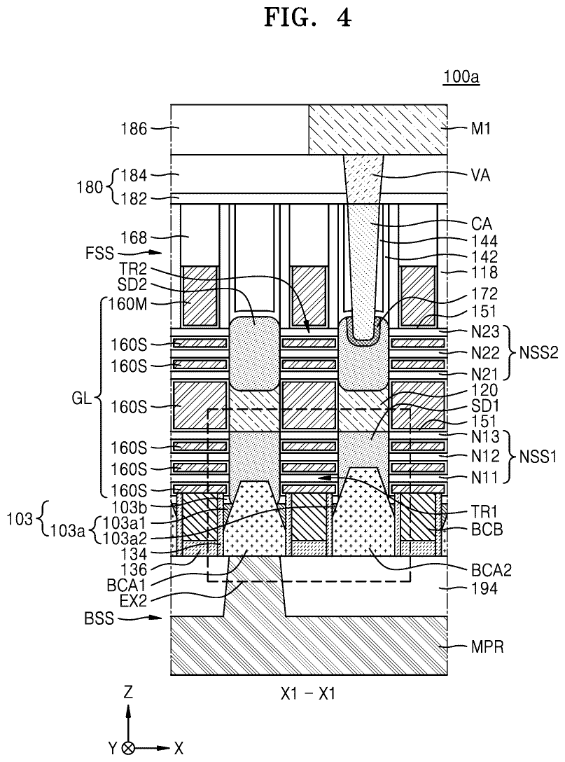

FIG. 4 is a cross-sectional view for explaining an integrated circuit device according to embodiments.

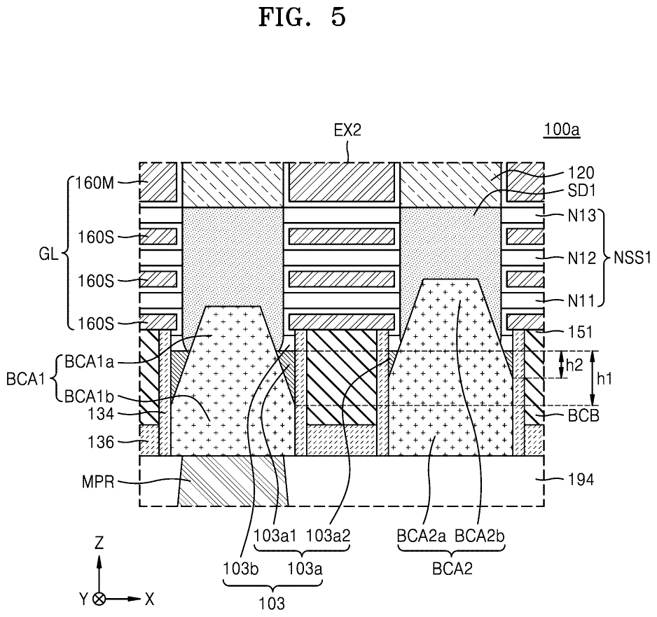

FIG. 5 is an enlarged cross-sectional view of a region EX2 of FIG. 4.

A description of parts common between the integrated circuit device 100a of FIGS. 1 to 3 and the integrated circuit device 100a of FIGS. 4 and 5 will be omitted, and differences will be mainly described.

Referring to FIGS. 4 and 5, the lower buffer layer 103a of the integrated circuit device 100a may include a first lower buffer layer 103a1 and a second lower buffer layer 103a2. Each of the first lower buffer layer 103al and the second lower buffer layer 103a2 may be arranged under the plurality of lower source/drain regions SD1. The first lower buffer layer 103al and the second lower buffer layer 103a2 may be spaced apart from one another in the first horizontal direction (X direction).

Thicknesses of the first lower buffer layer 103a1 and the second lower buffer layer 103a2 in the vertical direction (Z direction) may be different from one another. For example, the thickness h1 of the first lower buffer layer 103a1 in the vertical direction (Z direction) may be greater than the thickness h2 of the second lower buffer layer 103a2 in the vertical direction (Z direction).

The plurality of backside contacts BCA may include a first backside contact BCA1 and a second backside contact BCA2. The first backside contact BCA1 may include a first horizontal part BCAla and a first protrusion part BCA1b, and the second backside contact BCA2 may include a second horizontal part BCA2a and a second protrusion part BCA2b.

The first horizontal part BCA1a may be arranged under the first lower buffer layer 103a1 and may have a constant width in the first horizontal direction (X direction). The first protrusion part BCA1b may penetrate the first lower buffer layer 103al to be in contact with the lower source/drain region SD1. The first protrusion part BCA1b may be integrally formed with the first horizontal part BCAla, and may have a tapered shape in which a width in the first horizontal direction (X direction) decreases as a distance from a top surface of the first horizontal part BCAla increases, but embodiments are not limited thereto.

The second horizontal part BCA2a may be arranged under the second lower buffer layer 103a2 and may have a constant width in the first horizontal direction (X direction). In this case, the thickness of the second horizontal part BCA2a in the vertical direction (Z direction) may be greater than the thickness of the first horizontal part BCAla in the vertical direction (Z direction). For example, the thickness difference in the vertical direction (Z direction) between the second horizontal part BCA2a and the first horizontal part BCAla may be substantially the same as the thickness difference in the vertical direction (Z direction) between the first lower buffer layer 103a1 and the second lower buffer layer 103a2, but embodiments are not limited thereto. The second protrusion part BCA2b may penetrate the second lower buffer layer 103a2 to be in contact with the lower source/drain region SD1. The second protrusion part BCA2b may be integrally formed with the second horizontal part BCA2a, and may have a tapered shape in which a width in the first horizontal direction (X direction) decreases as a distance from a top surface of the second horizontal part BCA2a increases, but embodiments are not limited thereto.

The integrated circuit device 100s illustrated in FIGS. 4 and 5 may include the lower buffer layer 103a including silicon germanium and the upper buffer layer 103b including silicon. Through the epitaxial process, the surface roughness of the plurality of nanosheet stacks NSS1 and NSS2 may be improved by forming the plurality of nanosheet stacks NSS1 and NSS2 on the buffer layer 103. Accordingly, electron mobility is improved and channel resistance is reduced, thereby improving electrical characteristics of the integrated circuit device 100a.

In addition, by making the width of the backside contact BCA in the first horizontal direction (X direction) greater than the width of the lower source/drain area SD1 in the first horizontal direction (X direction), the contact resistance may be reduced, thereby improving the electrical characteristics of the integrated circuit device 100.

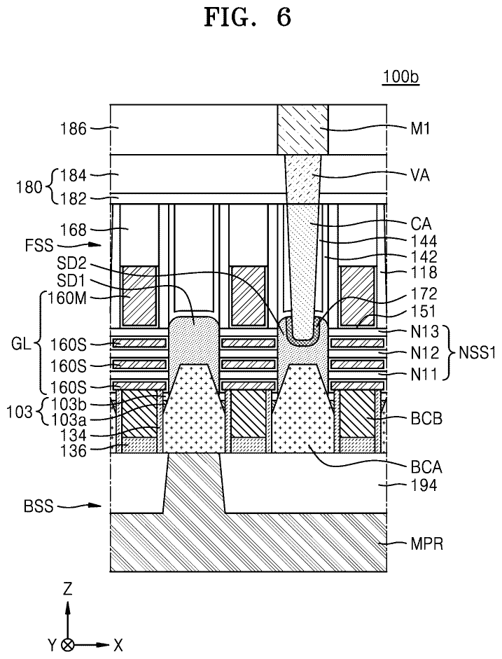

FIG. 6 is a cross-sectional view for explaining an integrated circuit device according to embodiments.

A description of parts common between the integrated circuit device 100 of FIGS. 1 to 3 and the integrated circuit device 100b of FIG. 6 will be omitted, and differences will be mainly described.

Referring to FIG. 6, unlike the integrated circuit devices 100 and 100a described with reference to FIGS. 1 to 5, an integrated circuit devices 100b is configured such that a plurality of transistors may not be stacked in the vertical direction (Z direction) and may be arranged in the horizontal direction (X direction and/or Y direction). Since the first source/drain region SD1 and the second source/drain region SD2 are not stacked in the vertical direction (Z direction), the insulating pattern 120 (see FIG. 2) may be omitted.

In addition, the plurality of upper nanosheet stacks NSS2 (see FIG. 2) may be omitted from the integrated circuit device 100b, and the plurality of lower nanosheet stacks NSS1, the first source/drain region SD1, and the second source/drain region SD2 may constitute a plurality of transistors.

The integrated circuit device 100b may include the first source/drain region SD1 and the second source/drain region SD2. The first source/drain region SD1 and the second source/drain region SD2 may be spaced apart from one another in the first horizontal direction (X direction).

The first source/drain region SD1 may include a semiconductor layer doped with a p-type dopant. For example, the first source/drain regions SD1 may include a Si layer doped with a p-type dopant or a SiC layer doped with a p-type dopant. The p-type dopants may be selected from boron (B) and gallium (G).

The second source/drain region SD2 may include a semiconductor layer doped with an n-type dopant. For example, the second source/drain regions SD2 may include a SiGe layer doped with an n-type dopant. The n-type dopants may be selected from phosphorus (P), arsenic (As), and antimony (Sb).

The plurality of buffer layers 103 may be arranged below the first source/drain region SD1 and the second source/drain region SD2, respectively. Each of the plurality of buffer layers 103 may include a lower buffer layer 103a and an upper buffer layer 103b. The upper buffer layer 103b may be arranged below the first source/drain region SD1 and the second source/drain region SD2, and the lower buffer layer 103a may be arranged below the upper buffer layer 103b. The lower buffer layer 103a and the upper buffer layer 103b may include different materials. For example, the upper buffer layer 103b may include silicon (Si), and the lower buffer layer 103a may include silicon germanium (SiGe). In this case, the germanium concentration of the lower buffer layer 103 a may be less than 5.5 %, but embodiments are not limited thereto. In another embodiment, the upper buffer layer 103b may be omitted, and the buffer layer 103 may include a silicon germanium single layer. In this case, as shown in FIGS. 4 and 5, the thicknesses of the plurality of lower buffer layers 103a may be different from one another.

The upper contact CA may be connected to at least one of the first source/drain region SD1 and the second source/drain region SD2. The backside contact BCA may be connected to at least one of the first source/drain region SD1 and the second source/drain region SD2. Each of the plurality of backside contacts BCA may be arranged to overlap the first source/drain region SD1 and/or the second source/drain region SD2 in the vertical direction (Z direction).

The plurality of backside gate contacts BCB may be spaced apart from the plurality of backside contacts BCA in the first horizontal direction (X direction) with the second gap-fill insulating layer 134 therebetween. The plurality of backside gate contacts BCB may be connected to the plurality of gate lines GL overlapping in the vertical direction (Z direction), respectively.

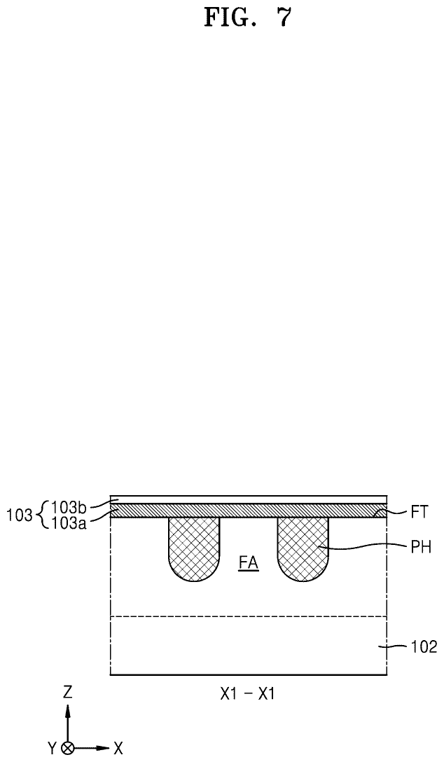

FIGS. 7 to 25 are cross-sectional views illustrated according to a process sequence for describing a method of manufacturing an integrated circuit device according to embodiments, and are cross-sectional views of a part corresponding to a cross section taken along a line X1-X1′ of FIG. 1.

Referring to FIG. 7, a plurality of recesses may be formed in the substrate 102, and a plurality of placeholders PH respectively filling the plurality of recesses may be formed. In this case, the substrate 102 may include semiconductors, such as Si or Ge, or compound semiconductors, such as SiGe, SiC, GaAs, InAs, InGaAs, or InP. The terms “SiGe”, “SiC”, “GaAs”, “InAs”, “InGaAs”, and “InP” used herein refer to materials composed of elements included in each term, and are not chemical formulae representing a stoichiometric relationship.

The placeholders PH may include silicon germanium (SiGe). For example, the placeholder PH may include a monocrystalline SiGe layer, a polycrystalline SiGe layer, an amorphous SiGe layer, or a combination thereof.

In embodiments, the placeholder PH may be deposited through various methods such as a PECVD process, an HDP CVD process, an ICP CVD process, a CCP CVD process, and an FCVD process using raw materials including an element precursor. For example, the placeholder PH may be formed by epitaxially growing the SiGe layer from the surface of the fin-type active area FA exposed by the recess. In this case, the placeholder PH may include a monocrystalline SiGe layer.

Thereafter, a buffer layer 103 covering the placeholder PH may be formed on the substrate 102. The buffer layer 103 may include a lower buffer layer 103a and an upper buffer layer 103b. The lower buffer layer 103a may include silicon germanium (SiGe), and the upper buffer layer 130b may include silicon (Si). In this case, the germanium concentration of the lower buffer layer 103 a may be less than 5.5 %, but embodiments are not limited thereto. The lower buffer layer 103a may be formed by epitaxially growing from the placeholder PH and the substrate 102, and the upper buffer layer 103b may be formed by epitaxially growing from the lower buffer layer 103a.

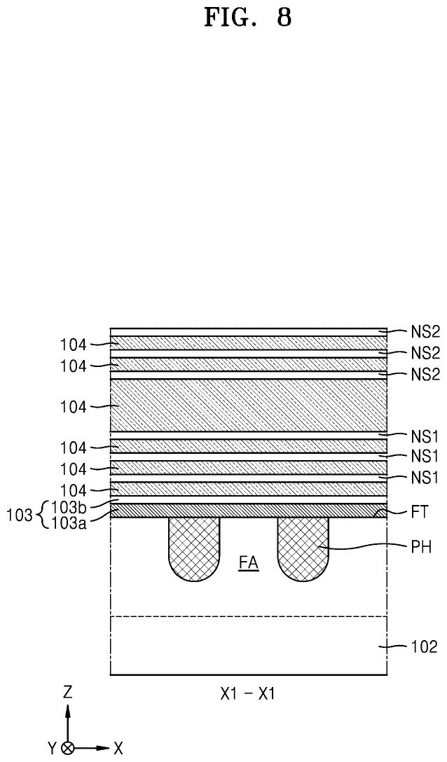

Referring to FIG. 8, a plurality of sacrificial semiconductor layers 104 and a plurality of nanosheet semiconductor layers NS1 and NS2 may be alternately stacked one layer by another on the upper buffer layer 103b. The plurality of nanosheet semiconductor layers NS1 and NS2 may include a plurality of lower nanosheet semiconductor layers NS1 and a plurality of upper nanosheet semiconductor layers NS2. The plurality of sacrificial semiconductor layers 104 and the plurality of nanosheet semiconductor layers NS1 and NS2 may include semiconductor materials having different etch selectivity. In embodiments, each of the plurality of nanosheet semiconductor layers NS1 and NS2 may include an Si layer and each of the plurality of sacrificial semiconductor layers 104 may include an SiGe layer. In embodiments, the Ge concentration in the plurality of sacrificial semiconductor layers 104 may be constant. The SiGe layers constituting the plurality of sacrificial semiconductor layers 104 may have a constant Ge concentration selected within a range of about 5 at % to about 60 at %, for example, about 10 at % to about 40 at %. The Ge concentration in the SiGe layers constituting the plurality of sacrificial semiconductor layers 104 may be variously selected as needed.

The plurality of sacrificial semiconductor layers 104, the plurality of nanosheet semiconductor layers NS1 and NS2, and a portion of the substrate 102 may be etched to form a fin-type active area FA in the substrate 102. After the fin-type active area FA is formed, a stacked structure of the plurality of sacrificial semiconductor layers 104 and the plurality of nanosheet semiconductor layers NS1 and NS2 may remain on the upper portion of the fin-type active area FA. Thereafter, a device isolation layer covering a lower sidewall of the fin-type active area FA may be formed on the substrate 102.

The surface roughness of the plurality of nanosheet semiconductor layers NS1 and NS2 may be improved by forming the plurality of sacrificial semiconductor layers 104 and the plurality of nanosheet semiconductor layers NS1 and NS2 on the lower buffer layer 103a including silicon germanium and the upper buffer layer 103b including silicon through an epitaxial process.

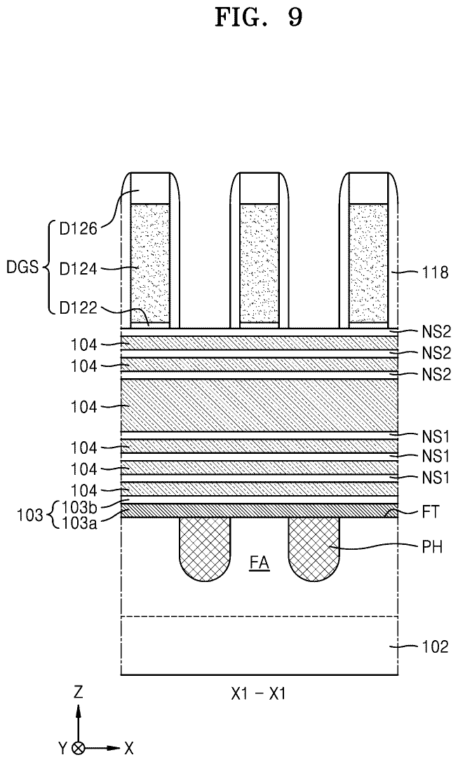

Referring to FIG. 9, a plurality of dummy gate structures DGS may be formed on the stack structure of the plurality of sacrificial semiconductor layers 104 and the plurality of nanosheet semiconductor layers NS1 and NS2.

Each of the plurality of dummy gate structures DGS may be formed to extend lengthwise in the second horizontal direction (Y direction). Each of the plurality of dummy gate structures DGS may have a structure in which an oxide layer D122, a dummy gate layer D124, and a capping layer D126 are sequentially stacked. In some embodiments, the dummy gate layer D124 may include polysilicon, and the capping layer D126 may include a silicon nitride layer.

Thereafter, a plurality of insulating spacers 118 covering both sidewalls of each of the plurality of dummy gate structures DGS may be formed.

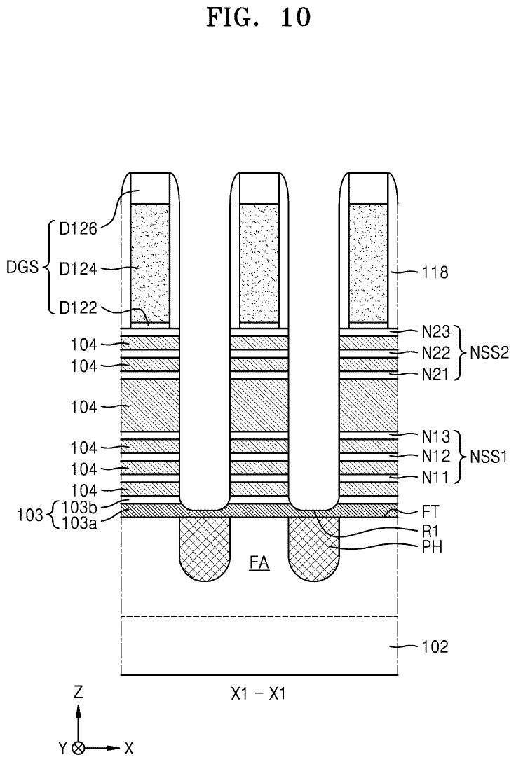

Referring to FIG. 10, a part of a plurality of sacrificial semiconductor layers 104 and a part of a plurality of nanosheet semiconductor layers NS1 and NS2 may be etched and removed using a plurality of dummy gate structures DGS and a plurality of insulating spacers 118 as etching masks.

A plurality of first recesses R1 may be formed by the etching process. The plurality of sacrificial semiconductor layers 104, the plurality of upper nanosheet stacks NSS2, and the plurality of lower nanosheet stacks NSS1 may be exposed by the plurality of first recesses R1. The plurality of first recesses R1 may be formed at positions overlapping the plurality of placeholders PH in the vertical direction (Z direction), respectively. In order to form the plurality of first recesses R1, etching may be performed using dry etching, wet etching, or a combination thereof.

By a process of forming the plurality of first recesses R1, the plurality of upper nanosheet semiconductor layers NS2 may be divided into a plurality of upper nanosheet stacks NSS2 each including a first upper nanosheet N21, a second upper nanosheet N22, and a third upper nanosheet N23. The plurality of lower nanosheet semiconductor layers NS1 may be divided into a plurality of lower nanosheet stacks NSS1 each including a first lower nanosheet N11, a second lower nanosheet N12, and a third lower nanosheet N13.

The process of forming the plurality of first recesses R1 may be removed by etching a portion of the buffer layer 103. In embodiments, the plurality of first recesses R1 may expose a sidewall of the upper buffer layer 103b and expose a portion of the lower buffer layer 103a. A vertical level of a bottom surface of the first recess R1 may be lower than a vertical level of a top surface of the lower buffer layer 103a.

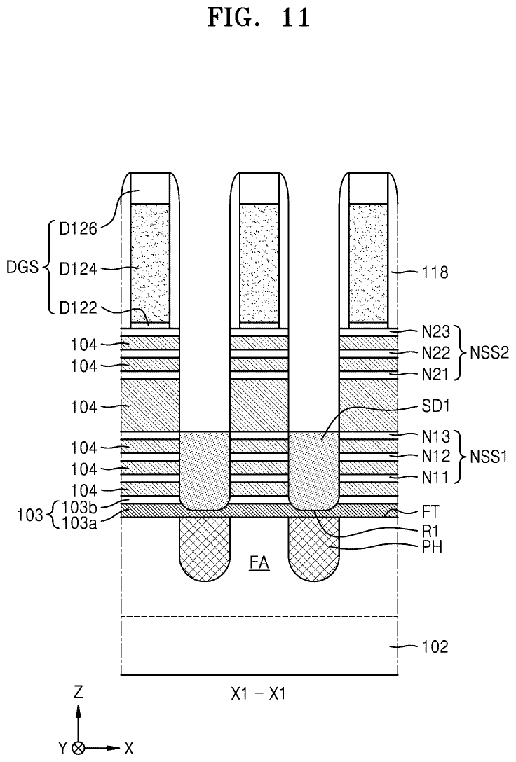

Referring to FIG. 11, a plurality of lower source/drain regions SD1 filling the plurality of first recesses R1 may be formed in the result of FIG. 10.

A selective epitaxial growth process may be performed to form the plurality of lower source/drain regions SD1. In the initial stage of the selective epitaxial growth process, a semiconductor layer may be locally epitaxially grown from surfaces of the upper buffer layer 103b and the lower buffer layer 103a exposed in the plurality of first recesses R1, surfaces of a plurality of first lower nanosheets N11, second lower nanosheets N12, and third lower nanosheets N13, and surfaces of the fin-type active area FA. Thereafter, as the selective epitaxial growth process proceeds, the semiconductor layer gradually grows to obtain the plurality of lower source/drain regions SD1 as illustrated in FIG. 11.

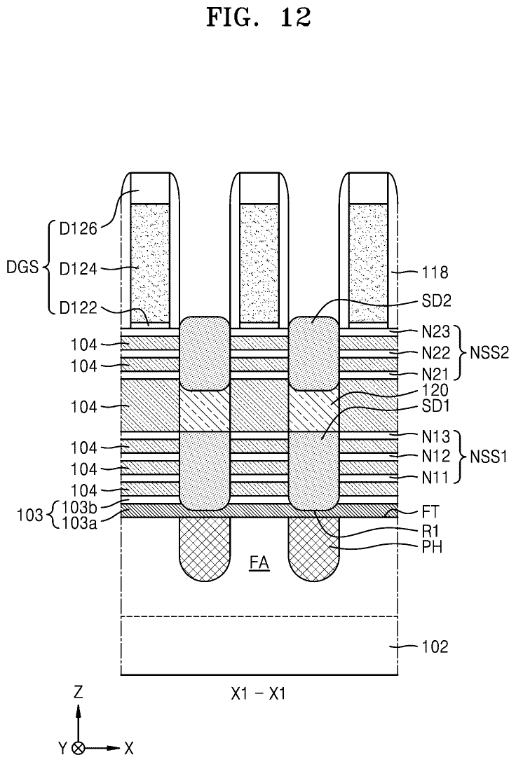

Referring to FIG. 12, in the result of FIG. 11, a plurality of insulating patterns 120 covering top surfaces of the plurality of lower source/drain regions SD1 and filling the plurality of first recesses R1, respectively, may be formed. In embodiments, the plurality of insulating patterns 120 may include silicon nitride (SiN), silicon oxide (SiO), SiCN, SiBN, SiON, SiOCN, SiBCN, SiOC, or a combination thereof.

Thereafter, a plurality of upper source/drain regions SD2 may be formed to cover top surfaces of the plurality of insulating patterns 120 and fill the plurality of first recesses R1, respectively.

A selective epitaxial growth process may be performed to form the plurality of upper source/drain regions SD2. In the initial stage of the selective epitaxial growth process, a semiconductor layer may be locally epitaxially grown from surfaces of a plurality of first upper nanosheets N21, second upper nanosheets N22, and third upper nanosheets N23 exposed in the plurality of first recesses R1. Thereafter, as the selective epitaxial growth process proceeds, the semiconductor layer gradually grows to obtain the plurality of upper source/drain regions SD2 as illustrated in FIG. 12.

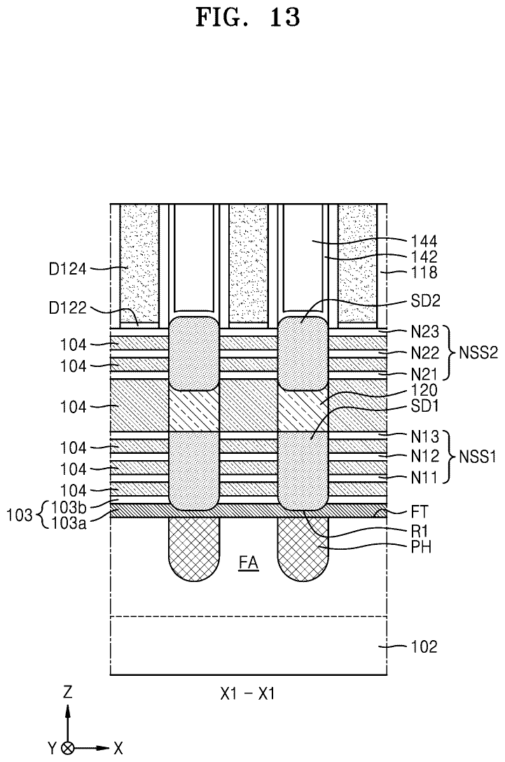

Referring to FIG. 13, an insulating liner 142 covering the plurality of upper source/drain regions SD2 may be formed in the formed result of FIG. 12, and an inter-gate insulating layer 144 may be formed on the insulating liner 142, and then the top surface of a capping layer D126 may be exposed by planarizing the insulating liner 142 and the inter-gate insulating layer 144. Then, the top surface of a dummy gate layer D124 may be exposed by removing the plurality of capping layers D126, and the insulating liner 142 and the inter-gate insulating layer 144 may be partially removed so that the top surface of the inter-gate insulating layer 144 and the top surface of the dummy gate layer D124 have approximately the same level.

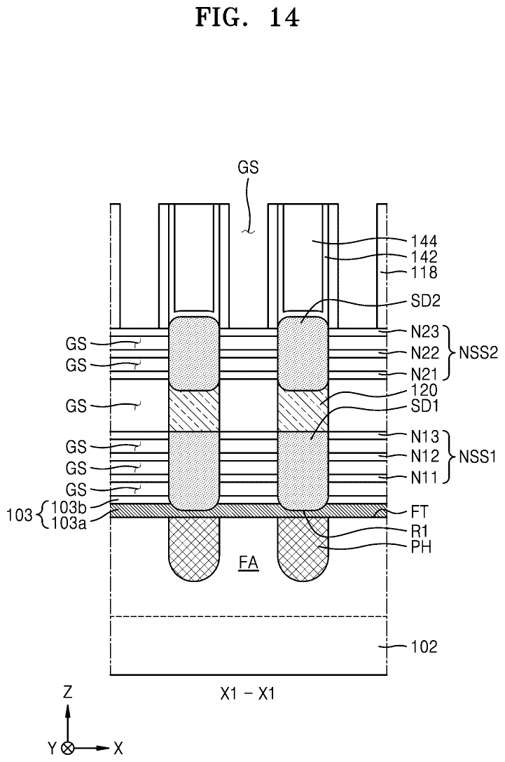

Referring to FIG. 14, a gate space GS may be provided by removing, from the result of FIG. 13, the dummy gate layer D124 and the oxide layer D122 below the dummy gate layer D124. Thereafter, the plurality of sacrificial semiconductor layers 104 remaining on the fin-type active area FA may be removed through the gate space GS to extend the gate space GS to the fin-type active area FA.

In embodiments, in order to selectively remove the plurality of sacrificial semiconductor layers 104, a difference in etching selectivity between the plurality of lower nanosheet stacks NSS1, the plurality of upper nanosheet stacks NSS2, and the plurality of sacrificial semiconductor layers 104 may be used. In order to selectively remove the plurality of sacrificial semiconductor layers 104, a liquid or gaseous etchant may be used. In embodiments, in order to selectively remove the plurality of sacrificial semiconductor layers 104, a CH3COOH-based etchant, for example, an etchant including a mixture of CH₃COOH, HNO₃, and HF, or an etchant including a mixture of CH₃COOH, H₂O₂, and HF, may be used, but the etchant is not limited to those described above.

After the gate space GS extends to the fin-type active area FA, the lower source/drain area SD1 and the upper source/drain area SD2 may be exposed through the gate space GS.

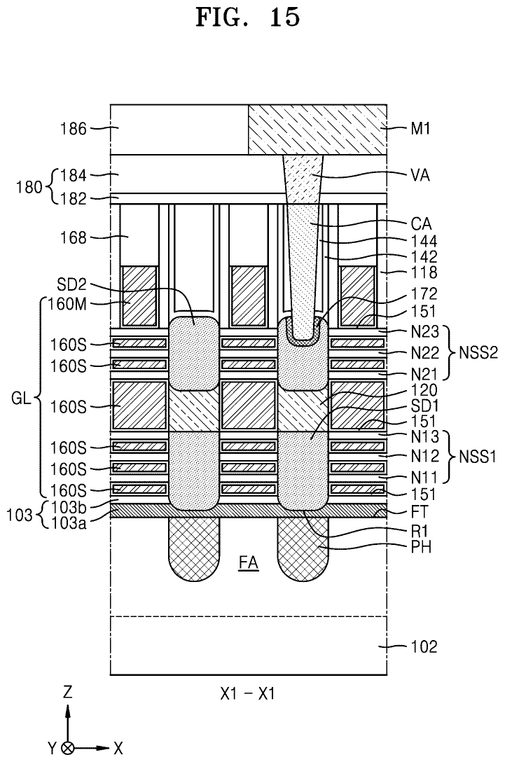

Referring to FIG. 15, a gate dielectric layer 151 covering exposed surfaces of each of the fin-type active region FA, the plurality of lower nanosheet stacks NSS1, the plurality of upper nanosheet stacks NSS2, the lower source/drain region SD1, and the upper source/drain region SD2, which are exposed via the gate space GS, may be formed in the result of FIG. 14. An atomic layer deposition (ALD) process may be used to form the gate dielectric layer 151.

Thereafter, a gate line GL covering the top surface of the gate dielectric layer 151 may be formed on the gate dielectric layer 151 while filling the gate space GS (see FIG. 15). A capping insulating pattern 168 filling the gate space GS may be formed on the gate line GL. The gate line GL may include metal, metal nitride, metal carbide, or a combination thereof. An ALD process or a CVD process may be used to form the gate line GL.

Thereafter, an upper contact hole may be formed through the insulating structure including the insulating liner 142 and the inter-gate insulating layer 144 to expose the upper source/drain region SD2, and then an upper contact CA may be formed through the upper contact hole. In this case, a metal silicide layer 172 may be formed between the upper contact CA and the upper source/drain region SD2.

Thereafter, an upper insulating structure 180 may be formed on the inter-gate insulating layer 144 and the upper contact CA, and a via contact VA may be formed to penetrate the upper insulating structure 180 and be connected to the upper contact CA. Subsequently, an upper insulating layer 186 on the upper insulating structure 180 and the via contact VA and a wiring line M1 penetrating the upper insulating layer 186 may be formed.

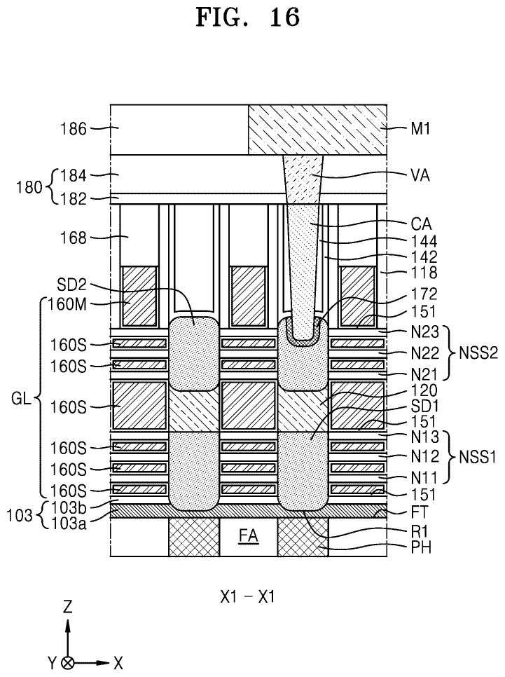

Referring to FIG. 16, a part of the placeholder PH and the fin-type active area FA may be selectively removed from the result of FIG. 15. Through a chemical mechanical polishing (CMP) process, the bottom surface of the placeholder PH and the bottom surface of the fin-type active area FA may be flattened, and the bottom surface of the placeholder PH may be exposed.

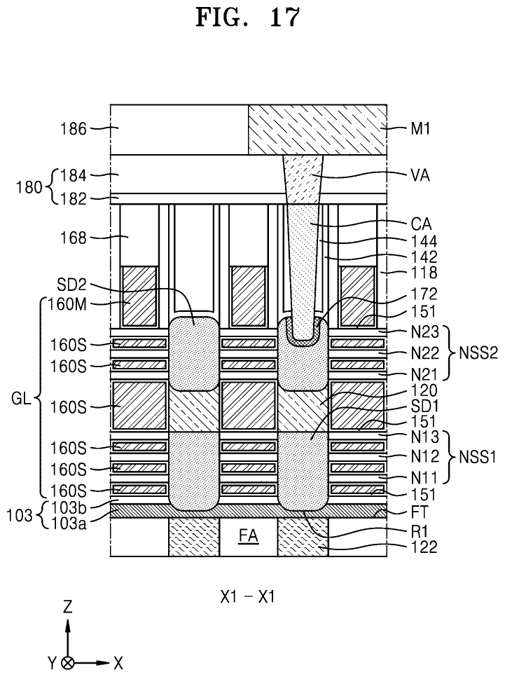

Referring to FIG. 17, the plurality of placeholders PH may be selectively removed from the result of FIG. 16. The etching process for removing the placeholders PH may use a difference in etching selectivity between the placeholder PH and the fin-type active area FA. As the placeholders PH are removed, a sidewall of the fin-type active area FA and a bottom surface of the lower buffer layer 103a may be exposed.

Thereafter, the lower insulating layers 122 may be formed to fill the spaces from which the placeholders PH have been removed. The lower insulating layer 122 may cover a bottom surface of the lower buffer layer 103a, and a sidewall and a bottom surface of the fin-type active area FA, which are exposed as the placeholder PH (refer to FIG. 16) is removed. Thereafter, the bottom surface of the lower insulating layer 122 and the bottom surface of the fin-type active area FA may be planarized through the CMP process. In embodiments, the process of forming the lower insulating layer 122 is performed by a thermal oxidation process, and the lower insulating layer 122 may include silicon oxide (SiO), but embodiments are not limited thereto.

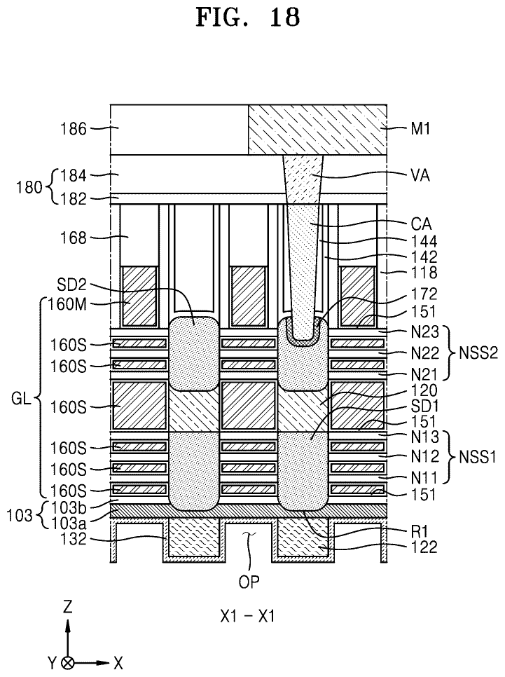

Referring to FIG. 18, the fin-type active area FA may be selectively removed from the result of FIG. 17. The etching process for removing the fin-type active area FA may use a difference in etching selectivity between the lower insulating layer 122 in the fin-type active area FA. As the fin-type active area FA is removed, the sidewall of the lower insulating layer 122 and the bottom surface of the lower buffer layer 103a may be exposed to form a plurality of openings OP.

Thereafter, the first gap-fill insulating layer 132 that conformally covers the plurality of openings OP may be formed. Specifically, the first gap-fill insulating layer 132 that conformally covers the sidewall of the lower insulating layer 122 and the bottom surface of the lower buffer layer 103a may be formed. The first gap-fill insulating layer 132 may include silicon nitride (SiN), silicon oxide (SiO), SiCN, SiBN, SiON, SiOCN, SiBCN, SiOC, or a combination thereof.

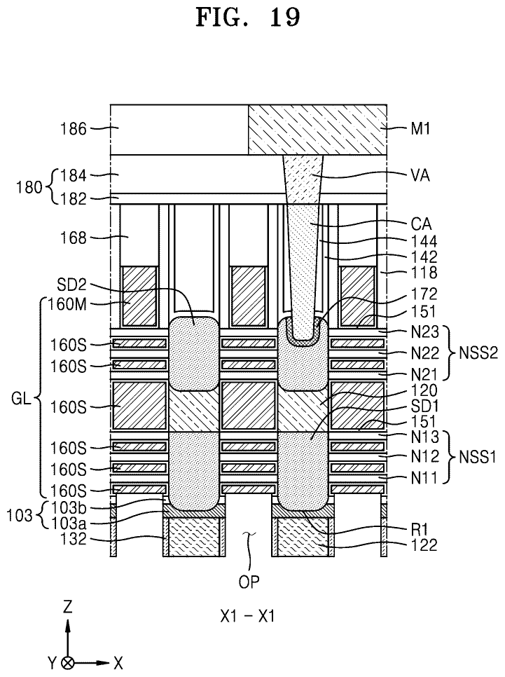

Referring to FIG. 19, the plurality of openings OP may be extended in the vertical direction (Z direction) in the result of FIG. 18. Specifically, portions of the first gap-fill insulating layer 132, the lower buffer layer 103a, the upper buffer layer 103b, and the gate dielectric layer 151 may be removed. Accordingly, the sidewall of the first gap-fill insulating layer 132, the sidewall of the lower buffer layer 103a, the sidewall of the upper buffer layer 103b, the sidewall of the gate dielectric layer 151, and the bottom surface of the sub-gate portion 160S arranged at the lowermost end may be exposed through the openings OP. In this case, portions of the lower buffer layer 103a and the upper buffer layer 103b covered by the first gap-fill insulating layer 132 and the lower insulating layer 122 may remain.

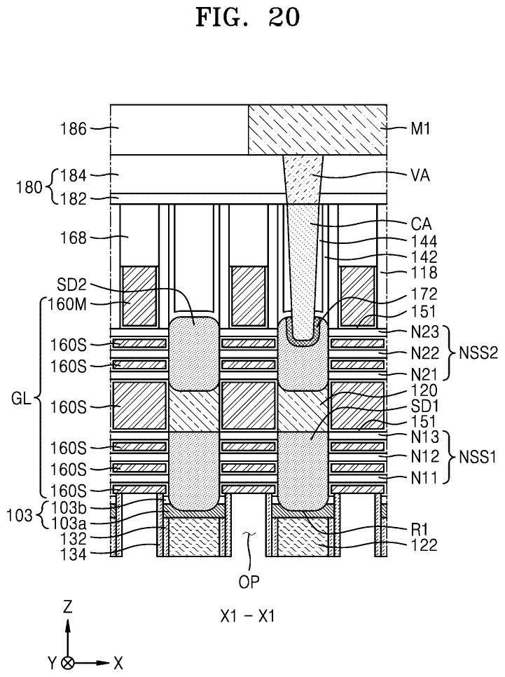

Referring to FIG. 20, thereafter, a second gap-fill insulating layer 134 that conformally covers the plurality of openings OP may be formed. Specifically, the second gap-fill insulating layer 134 may be formed to conformally cover a sidewall of the first gap-fill insulating layer 132, a sidewall of the lower buffer layer 103a, a sidewall of the upper buffer layer 103b, a sidewall of the gate dielectric layer 151, and a bottom surface of the sub-gate portion 160S arranged at the lowermost end. Thereafter, a portion of the second gap-fill insulating layer 134 may be removed to expose a bottom surface of the sub-gate portion 160S arranged at the lowermost end.

The second gap-fill insulating layer 134 may include silicon nitride (SiN), silicon oxide (SiO), SiCN, SiBN, SiON, SiOCN, SiBCN, SiOC, or a combination thereof. In embodiments, the second gap-fill insulating layer 134 may include the same material as the constituent material of the first gap-fill insulating layer 132. In embodiments, the second gap-fill insulating layer 134 may include the different material from the constituent material of the first gap-fill insulating layer 132.

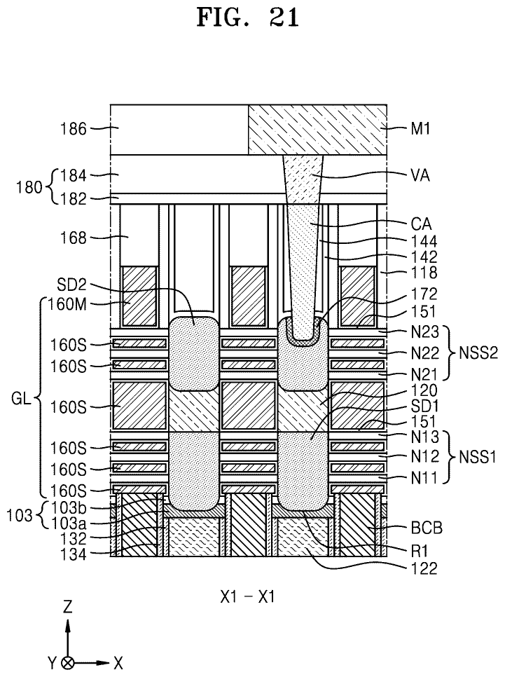

Referring to FIG. 21, a plurality of backside gate contacts BCB filling the plurality of openings OP (refer to FIG. 20), respectively, may be formed in the result of FIG. 20. The plurality of backside gate contacts BCB may be connected to the plurality of gate lines GL, respectively. The backside gate contacts BCB may include W, Cu, Al, Ti, Ta, TiN, TaN, an alloy thereof, or a combination thereof, but are not limited thereto.

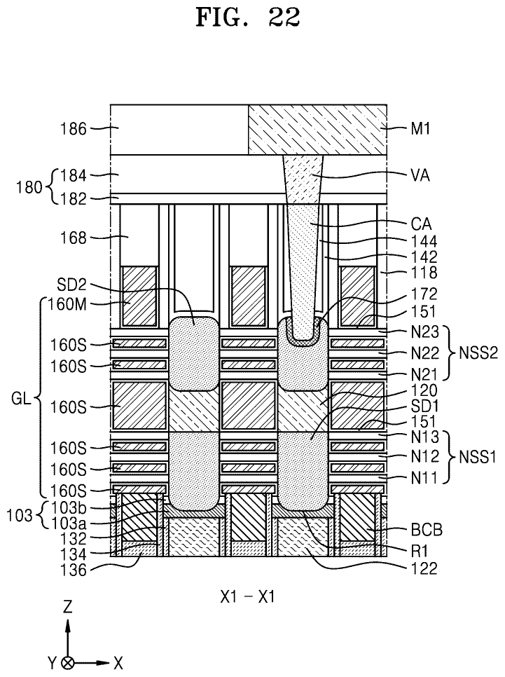

Referring to FIG. 22, a portion of the plurality of backside gate contacts BCB in the result of FIG. 21 may be removed, and a third gap-fill insulating layer 136 may be formed to fill the space from which the plurality of backside gate contacts BCB have been removed. The third gap-fill insulating layer 136 may include silicon nitride (SiN), silicon oxide (SiO), SiCN, SiBN, SiON, SiOCN, SiBCN, SiOC, or a combination thereof. Thereafter, through the CMP process, the bottom surface of the lower insulating layer 122, the bottom surface of the first gap-fill insulating layer 132, the bottom surface of the second gap-fill insulating layer 134 and the bottom surface of the third gap-fill insulating layer 136 may be planarized

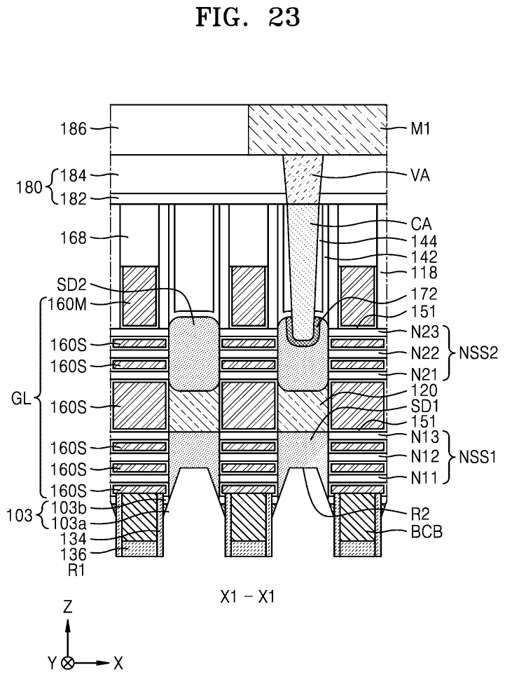

Referring to FIG. 23, a plurality of second recesses R2 may be formed in the result of FIG. 22. In the process of forming the second recess R2, the lower insulating layer 122 and the first gap-fill insulating layer 132 may be removed to expose the bottom surface of the lower buffer layer 103a. Thereafter, a part of the lower buffer layer 103a, a part of the upper buffer layer 103b, and a part of the lower source/drain region SD1 may be removed to form the second recess R2. The plurality of second recesses R2 are each formed at a position that overlaps the plurality of lower source/drain regions SD1 in the vertical direction (Z direction), and the plurality of lower source/drain regions SD1 may be exposed through the plurality of second recesses R2. In order to form the plurality of second recesses R2, etching may be performed using dry etching, wet etching, or a combination thereof.

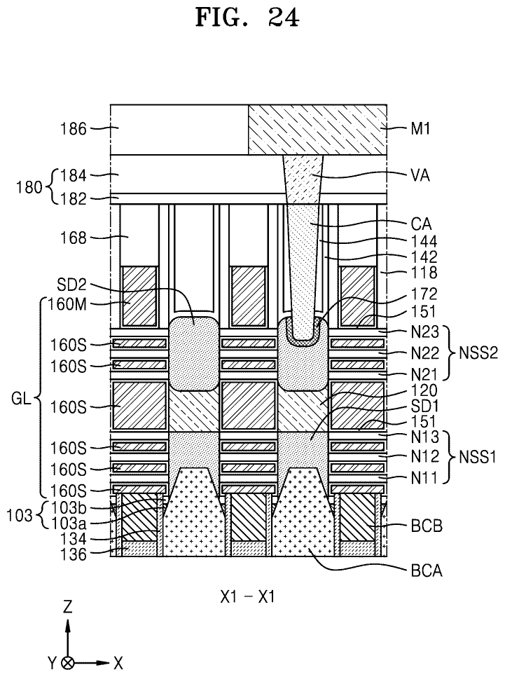

Referring to FIG. 24, a plurality of backside contacts BCA filling the plurality of second recesses R2, respectively, may be formed in the result of FIG. 23. In some embodiments, each of the plurality of backside contacts BCA may include a metal, a conductive metal nitride, or a combination thereof. For example, each of the plurality of backside contacts BCA may include W, Cu, Al, Ti, Ta, TiN, TaN, alloys thereof, or a combination thereof, but is not limited thereto. A metal silicide layer may be formed between the plurality of backside contacts BCA and the plurality of lower source/drain regions SD1.

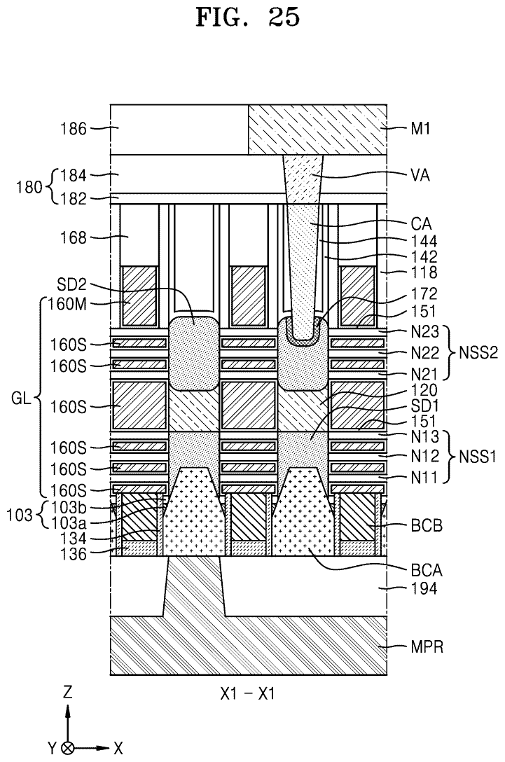

Referring to FIG. 25, the integrated circuit device 100 of FIGS. 1 to 3 may be manufactured by forming a lower insulating layer 194 covering the backside contact BCA, the second gap-fill insulating layer 134 and the third gap-fill insulating layer 136, and forming a metal power rail MPR connected to the lower source/drain region SD1 while penetrating the lower insulating layer 194, in the result of FIG. 24.

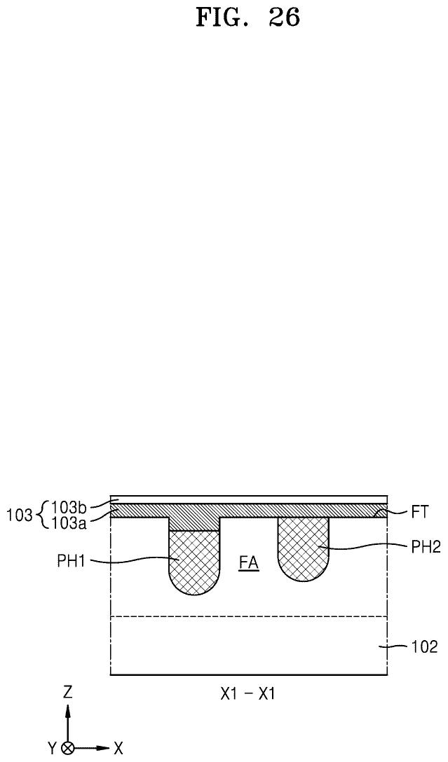

FIGS. 26 to 28 are cross-sectional views illustrated according to a process sequence for describing a method of manufacturing an integrated circuit device according to embodiments, and are cross-sectional views of a part corresponding to a cross section taken along a line X1-X1′ of FIG. 1.

In FIGS. 26 to 28, the same reference numerals as in FIGS. 1 to 25 denote the same members, and detailed descriptions thereof will be omitted.

Referring to FIG. 26, a plurality of recesses may be formed in the substrate 102, and a plurality of placeholders PH respectively filling the plurality of recesses may be formed. In this case, the substrate 102 may include semiconductors, such as Si or Ge, or compound semiconductors, such as SiGe, SiC, GaAs, InAs, InGaAs, or InP.

The plurality of placeholders PH may include a first placeholder PH1 and a second placeholder PH2. As the depths of the plurality of recesses in the vertical direction (Z direction) are formed differently, the depths of the first placeholder PH1 and the second placeholder PH2 filling the plurality of recesses may be different. For example, a vertical level of the bottom surface of the first placeholder PH1 may be lower than a vertical level of the bottom surface of the second placeholder PH2. A vertical level of the top surface of the first placeholder PH1 may be lower than a vertical level of the top surface of the second placeholder PH2.

Each of the first placeholder PH1 and the second placeholder PH2 may include silicon germanium (SiGe). For example, the first placeholder PH1 and the second placeholder PH2 may each include a single crystalline SiGe layer, a polycrystalline SiGe layer, an amorphous SiGe layer, or a combination thereof.

Thereafter, a buffer layer 103 covering the placeholder PH may be formed on the substrate 102. The buffer layer 103 may include a lower buffer layer 103a and an upper buffer layer 103b. The lower buffer layer 103a may include silicon germanium (SiGe), and the upper buffer layer 130b may include silicon (Si). In this case, the germanium concentration of the lower buffer layer 103 a may be less than 5.5 %, but embodiments are not limited thereto.

The lower buffer layer 103a may cover the top surfaces of the first placeholder PH1 and the second placeholder PH2. As the vertical levels of the top surfaces of the first placeholder PH1 and the second placeholder PH2 are formed differently, the thickness of the lower buffer layer 103a overlapping the first placeholder PH1 in the vertical direction (Z direction) may be thicker than the thickness of the lower buffer layer 103a overlapping the second placeholder PH2 in the vertical direction (Z direction).

In this case, the top surface of the lower buffer layer 103a covering the first placeholder PH1 and the second placeholder PH2 may be coplanar. Accordingly, even if the vertical levels of the top surfaces of the first placeholder PH1 and the second placeholder PH2 are formed differently, the subsequent process may be performed without a separate planarization process.

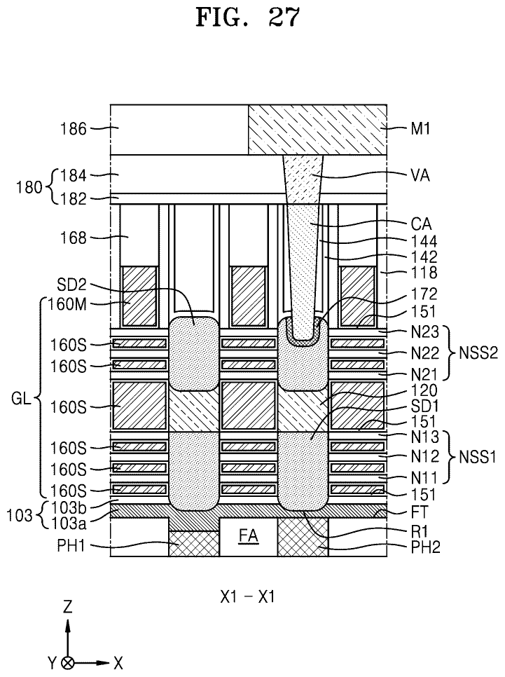

Referring to FIG. 27, the processes described with reference to FIGS. 8 to 16 may be performed. However, after the planarization process, the thickness of the first placeholder PH1 in the vertical direction (Z direction) may be less than the thickness of the second placeholder PH2 in the vertical direction (Z direction).

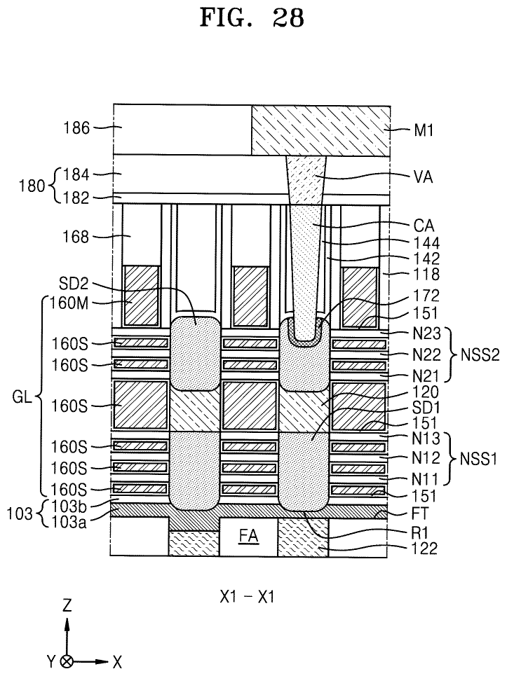

Referring to FIG. 28, the first placeholder PH1 and the second placeholder PH2 may be selectively removed from the result of FIG. 27. The etching process for removing the first placeholder PH1 and the second placeholder PH2 may use a difference in etching selectivity between the first placeholder PH1 and the second placeholder PH2 and the fin-type active area FA. Thereafter, the lower insulating layer 122 may be formed to fill the spaces in which the first placeholder PH1 and the second placeholder PH2 are removed. The thickness of the lower insulating layer 122 in the vertical direction (Z direction), which replaces the position of the first placeholder PHI may be less than the thickness of the lower insulating layer 122 in the vertical direction (Z direction), which replaces the position of the second placeholder PH2.

Thereafter, the integrated circuit device 100a of FIGS. 4 and 5 may be manufactured by performing the processes described with reference to FIGS. 18 to 25.

While the inventive concept has been particularly shown and described with reference to embodiments thereof, it will be understood that various changes in form and details may be made therein without departing from the spirit and scope of the following claims.

What is claimed is:

1. An integrated circuit device comprising:
a plurality of gate lines spaced apart in a first substantially horizontal direction and extending in a second substantially horizontal direction crossing the first substantially horizontal direction;
a plurality of lower source/drain regions of a first conductivity type arranged between the plurality of gate lines adjacent to one another at a first vertical level;
a plurality of upper source/drain regions of a second conductivity type arranged between the plurality of gate lines adjacent to one another at a second vertical level higher than the first vertical level and overlapping the lower source/drain regions in a substantially vertical direction;
a nanosheet stack including at least one nanosheet connected to the plurality of lower source/drain regions or the plurality of upper source/drain regions;
a plurality of buffer layers arranged under the plurality of lower source/drain regions, respectively; and
a plurality of backside contacts penetrating the plurality of buffer layers and respectively connected to the plurality of lower source/drain regions.

2. The integrated circuit device of claim 1, wherein the plurality of buffer layers each comprise silicon germanium.

3. The integrated circuit device of claim 1, wherein each of the plurality of backside contacts comprises:
a horizontal part arranged under the buffer layer and having a first horizontal width that is constant; and
a tapered protrusion that penetrates the buffer layer and is connected to the lower source/drain region.

4. The integrated circuit device of claim 3, wherein the first horizontal width of the horizontal part is greater than the first horizontal width of the lower source/drain region.

5. The integrated circuit device of claim 1, wherein:
the plurality of lower source/drain regions comprise a first lower source/drain region and a second lower source/drain region spaced apart from one another in the first substantially horizontal direction,
the plurality of buffer layers comprise a first buffer layer arranged under the first lower source/drain region and a second buffer layer arranged under the second lower source/drain region, and
a vertical thickness of the first buffer layer is greater than a vertical thickness of the second buffer layer.

6. The integrated circuit device of claim 5, wherein:
the plurality of backside contacts comprise a first backside contact penetrating the first buffer layer and a second backside contact penetrating the second buffer layer, and
a vertical thickness of the horizontal part of the first buffer layer is less than a vertical thickness of the horizontal part of the second buffer layer.

7. The integrated circuit device of claim 1, further comprising:
a gap-fill insulating layer covering the sidewalls of the plurality of buffer layers and the sidewalls of the plurality of backside contacts; and
a plurality of backside gate contacts spaced apart from the backside contact in the first substantially horizontal direction with the gap-fill insulating layer therebetween and connected to the plurality of gate lines, respectively.

8. The integrated circuit device of claim 7, wherein a vertical level of a bottom surface of the plurality of backside contacts and a vertical level of a bottom surface of the plurality of backside gate contacts are different from one another.

9. The integrated circuit device of claim 7, wherein the first horizontal width between the sidewalls of the plurality of buffer layers respectively in contact with the gap-fill insulating layer is greater than the first horizontal width of the lower source/drain region.

10. An integrated circuit device comprising:
a plurality of gate lines spaced apart in a first substantially horizontal direction and extending in a second substantially horizontal direction crossing the first substantially horizontal direction;
a plurality of source/drain regions arranged between adjacent ones of the plurality of gate lines;
a nanosheet stack including one or more nanosheets connected to the plurality of source/drain regions;
a plurality of buffer layers arranged under the plurality of source/drain regions, respectively; and
a plurality of backside contacts penetrating the plurality of buffer layers and respectively connected to the plurality of source/drain regions.

11. The integrated circuit device of claim 10, wherein each of the plurality of buffer layers comprises:
an upper buffer layer including silicon; and
a lower buffer layer arranged below the upper buffer layer and including silicon germanium.

12. The integrated circuit device of claim 10, wherein each of the plurality of backside contacts comprises:
a horizontal part arranged under the buffer layer and having a first horizontal width that is constant; and
a tapered protrusion that penetrates the buffer layer and is connected to the source/drain region.

13. The integrated circuit device of claim 10, wherein a maximum width of the plurality of backside contacts in the first substantially horizontal direction is greater than a maximum width of the plurality of source/drain regions.

14. The integrated circuit of claim 10, wherein:
the plurality of source/drain regions comprise a first source/drain region and a second source/drain region spaced apart from one another in the first substantially horizontal direction,
the plurality of buffer layers comprise a first buffer layer arranged under the first source/drain region and a second buffer layer arranged under the second source/drain region, and
a vertical thickness of the first buffer layer is greater than a vertical thickness of the second buffer layer.

15. The integrated circuit device of claim 14, wherein
the plurality of backside contacts comprise a first backside contact penetrating the first buffer layer and a second backside contact penetrating the second buffer layer, and
a vertical thickness of the horizontal part of the first buffer layer is less than a vertical thickness of the horizontal part of the second buffer layer.

16. The integrated circuit device of claim 10, wherein:
a gap-fill insulating layer covering the sidewalls of the plurality of buffer layers and the sidewalls of the plurality of backside contacts; and
a plurality of backside gate contacts spaced apart from the backside contact in the first substantially horizontal direction with the gap-fill insulating layer therebetween and connected to the plurality of gate lines, respectively.

17. The integrated circuit device of claim 16, wherein the first horizontal width between the sidewalls of the plurality of buffer layers respectively in contact with the gap-fill insulating layer is greater than the first horizontal width of the source/drain region.

18. An integrated circuit device comprising:
a plurality of lower source/drain regions;
a plurality of upper source/drain regions spaced apart in a substantially vertical direction from the plurality of lower source/drain regions;
a lower nanosheet stack connected to the plurality of lower source/drain regions and including a plurality of lower nanosheets spaced apart from one another in the vertical direction;
an upper nanosheet stack connected to the plurality of upper source/drain regions and including a plurality of upper nanosheets spaced apart from one another in the substantially vertical direction;
a plurality of gate lines spaced apart from one another in a first substantially horizontal direction, extending in a second substantially horizontal direction crossing the first substantially horizontal direction, and surrounding the plurality of lower nanosheets and the plurality of upper nanosheets;
a plurality of upper contacts connected to the plurality of upper source/drain regions;
a plurality of buffer layers including silicon germanium and arranged under the plurality of lower source/drain regions; and
a plurality of backside contacts respectively penetrating the plurality of buffer layers and connected to the plurality of lower source/drain regions.

19. The integrated circuit device of claim 18, wherein a maximum width of the plurality of backside contacts in the first substantially horizontal direction is greater than a maximum width of the plurality of lower source/drain regions.

20. The integrated circuit device of claim 18, wherein:
a gap-fill insulating layer covering the sidewalls of the plurality of buffer layers and the sidewalls of the plurality of backside contacts; and
a plurality of backside gate contacts spaced apart from the backside contact in the first substantially horizontal direction with the gap-fill insulating layer therebetween and connected to the plurality of gate lines, respectively.
